(19) United States
(12) Patent Application Publication
(10) Pub. No.: US 2001/0015437 A1
(43) Pub. Date: Aug. 23, 2001

(54) GaN field-effect transistor, inverter device, and production processes therefor

(76) Inventors: Hirotatsu Ishii, Yokohama-shi (JP); Seikoh Yoshida, Toride-shi (JP)

Correspondence Address: KNOBBE MARTENS OLSON & BEAR LLP, 620 NEWPORT CENTER DRIVE, SIXTEENTH FLOOR, NEWPORT BEACH, CA, 92660, US

(21) Appl. No.: 09/770,526

(22) Filed: Jan. 25, 2001

(30) Foreign Application Priority Data
Jan. 25, 2000 (JP) 2000-15878
Mar. 3, 2000 (JP) 2000-58829

(51) Int. Cl. H01L 29/06; H01L 31/0328; H01L 31/0336; H01L 31/072; H01L 31/109; H01L 21/3205; H01L 21/4763

(52) U.S. Cl. 257/12; 438/590

(57) ABSTRACT

A process of forming a high-resistance GaN crystal layer which is useful in producing a GaN FET. The high-resistance GaN crystal layer is formed by doping a GaN crystal with one or more acceptor-type impurities selected from the group consisting of C, Mg and Zn during epitaxial growth thereof. Specifically, during the epitaxial growth of the GaN crystal, the GaN crystal is doped with Mg or Zn in an atmosphere of hydrogen at a temperature of 600° C. or higher, or the GaN crystal is doped with Mg or Zn at a concentration of 1×10¹⁷ cm⁻³ or higher and then is doped with C at a concentration of 1×10¹⁸ cm⁻³ or higher. The GaN layer may be ion-implanted with an acceptor such as C, Mg or Zn or with a donor such as Si, to control the carrier density and thus the threshold value.

### BACKGROUND OF THE INVENTION

1. Field of the Invention

The present invention relates to a field-effect transistor and an inverter device formed using GaN-based materials which ensure excellent operation characteristics in high-temperature environments, particularly, a field-effect transistor and an inverter device having a high-resistance GaN crystal layer as their buffer layer, and to processes for producing such devices. More particularly, the present invention relates to a production process suited for forming a high-resistance GaN crystal layer.

2. Description of the Related Art

MES (metal-semiconductor) type FETs (field-effect transistors) using compound semiconductor materials are in most cases formed using GaAs-based materials in the manner described below, for example.

First, on a semi-insulating substrate made of single-crystal GaAs, a high-resistance buffer layer of undoped GaAs (AlGaAs) is formed by MOCVD (metal organic camical vapor deposition), for example. Then, using TMG (trimethyl gallium) or TMA (trimethyl aluminum) together with arsine (AsH₃) and also using silane gas as n-type dopant, an n-type AlGaAs crystal layer is formed on the buffer layer as an active layer.

Subsequently, an insulating film of SiO₂ or the like is deposited on the n-type AlGaAs crystal layer by plasma CVD, for example, followed by patterning of the insulating film by photolithography or chemical etching to form openings in the insulating film at locations where source, drain and gate electrodes are to be formed. Thus, the n-type AlGaAs crystal layer is exposed at the openings from which the insulating layer has been removed. Then, AuGe/Ni/Au, for example, is deposited on the thus-exposed portions as the source and drain electrodes, and Al is deposited on the other exposed portion as the gate electrode, thereby forming an FET.

On the other hand, it is known that, as compared GaAs FETs described above, GaN FETs show good characteristics at high temperatures and can operate without entailing thermal runaway even in high-temperature environments of 400° C. or thereabouts. With a GaN-based material, however, it is difficult to obtain a large-diameter single-crystal substrate, unlike GaAs crystal. Accordingly, it is impossible to produce a GaN FET by the process of first preparing a GaN single-crystal substrate and then epitaxially growing a GaN crystal on the single-crystal substrate. Conventionally, therefore, a non-GaN material such as sapphire, SiC or GaAs is used to form the substrate, and after an undoped GaN crystal layer as a buffer layer is formed on the substrate by GS-MBE, MOCVD or the like, an n-type GaN crystal layer as an active layer is formed on the GaN crystal layer, thereby producing a GaN FET.

In order for the GaN FET to operate satisfactorily, it is necessary that the undoped GaN crystal layer located under the n-type active layer should have high resistance. However, the undoped GaN crystal layer formed in the above manner has large defects therein attributable to vacancy of nitrogen and the nitrogen vacancy acts as n-type donor, with the result that the undoped GaN crystal layer shows small n-type resistance.

Some GaN FETs have a heterojunction structure in which an AlN or AlGaN layer is grown on n-type or undoped GaN, for example, and are provided with a gate of MIS (metal-insulator-semiconductor) structure using the AlN or AlGaN. Although the operation characteristics of GaN FETs having such device structure are not completely clarified yet, presumably piezopolarization or spontaneous polarization takes place at the interface between AlN (or AlGaN) and GaN and high driving performance is attained by means of the interface where high-density carriers are induced.

In the case of AlGaAs/GaAs heterojunction, even if AlGaAs is doped at high density, its electron density (surface density of carriers) is approximately 10¹² cm⁻² at the most. In the case of AlGaN/GaN heterojunction, by contrast, an electron density of the order of 10¹³ cm⁻² can be obtained even if doping is not performed on purpose. Further, where the gate length is short, electron mobility difference poses no substantial problem. It is therefore considered that GaN FETs have higher driving performance than GaAs FETs because of their higher electron density attained by the AlGaN/GaN material.

In FETs using AlGaAs/GaAs heterojunction, the distance between the gate-Schottky junction and the interface of the heterojunction is adjusted by, for example, etching the upper portion of the AlGaAS layer, to thereby control the threshold value. In GaN FETs, for example, in AlGaN/GaN FETs, however, it is difficult to etch the AlGaN layer itself. Even if the AlGaN layer is etched by a plasma process, it is very likely that the etched surface is damaged by the plasma. Further, because of its good lattice matching, the AlGaN layer is usually formed as a thin film of 20 nm or less, and it is therefore difficult to control the threshold value after the etching.

### SUMMARY OF THE INVENTION

An object of the present invention is to provide a process of forming a high-resistance GaN crystal layer which solves the above problems encountered when producing GaN FETs.

To achieve the above object, according to the present invention, a GaN crystal is doped with one or more acceptor-type impurities selected from the group consisting of C (carbon), Mg (magnesium) and Zn (zinc) during epitaxial growth thereof.

Specifically, the present invention provides a process of forming a high-resistance GaN crystal layer, wherein a GaN crystal is doped with Mg or Zn in an atmosphere of hydrogen at a temperature of 600° C. or higher during epitaxial growth thereof. The present invention also provides a process of forming a high-resistance GaN crystal layer, wherein a GaN crystal is doped with Mg or Zn at a concentration of 1×10^{17 cm}⁻³ or higher and then doped with C at a concentration of 1×10¹⁸ cm⁻³ or higher during epitaxial growth thereof.

There is also provided according to the present invention a process of forming a high-resistance GaN crystal layer, wherein a GaN crystal is ion-implanted with one or more acceptor-type impurities selected from the group consisting of C, Mg and Zn. Further, the present invention provides a process of forming a high-resistance GaN crystal layer, wherein, with a GaN crystal heated to 400° C. or higher, the GaN crystal is ion-implanted with one or more acceptor-type impurities selected from the group consisting of C, Mg and Zn.

Another object of the present invention is to provide a GaN field-effect transistor and an inverter device which have excellent operation characteristics in high-temperature environments, and more particularly, to provide a field-effect transistor and an inverter device which have a device structure permitting the operating threshold value to be optimally set with ease and good controllability.

To achieve the above object, a field-effect transistor according to the present invention has a device structure in which an AlN or AlGaN layer is grown on a GaN layer to constitute a heterojunction, and a gate of MIS structure is formed on the GaN layer with the AlN or AlGaN layer therebetween. The field-effect transistor includes a high-resistance GaN crystal layer as a channel region located right under the gate, and the high-resistance GaN crystal layer is doped with one or more acceptor-type impurities selected from the group consisting of C, Mg and Zn during epitaxial growth thereof. The channel region located right under the gate may alternatively be a region whose carrier density has been controlled by ion implantation.

An inverter device according to the present invention has a GaN layer, an AlN or AlGaN layer grown on the GaN layer to constitute a heterojunction, and a plurality of gates formed adjacent to each other, each gate having an MIS structure formed on the GaN layer with the AlN or AlGaN layer therebetween, wherein a channel region located right under one of the adjacent gates is a region whose carrier density has been controlled by ion implantation.

Preferably, the adjacent gates comprise the gate of a first field-effect transistor for performing enhancement mode operation and the gate of a second field-effect transistor for performing depletion mode operation. The first enhancement mode field-effect transistor and the second depletion mode field-effect transistor are formed adjacent to each other to constitute the inverter device.

A production process according to the present invention comprises: forming an AlN or AlGaN layer on a GaN layer to constitute a heterojunction; ion-implanting a predetermined quantity of impurity into a channel region formed in the GaN layer to control carrier density thereof; forming a gate electrode on a region of the AlN or AlGaN layer located over the ion-implanted channel region; and forming source and drain regions on opposite sides of the channel region.

A process of producing a semiconductor device according to the present invention comprises: forming an AlN or AlGaN layer on a GaN-based substrate to constitute a heterojunction; ion-implanting a predetermined quantity of impurity into one of a plurality of channel regions of the substrate situated adjacent to each other to control carrier density thereof; forming a gate electrode on a region of the AlN or AlGaN layer located over each channel region; and forming source and drain regions on opposite sides of each channel region.

Specifically, in the field-effect transistor/inverter device production process according to the present invention, prior to the formation of a gate electrode on the AlN or AlGaN layer to form a gate with MIS structure, a predetermined quantity of impurity is ion-implanted into the channel region right under the gate, to control the carrier density and thereby optimally set the threshold value of a field-effect transistor (FET) incorporating the gate. The quantity of impurity which is ion-implanted to control the carrier density is set such that the ionized impurity can be produced in a quantity enough to substantially compensate for, that is, electrically cancel out carriers that will be induced in the channel region if no ion-implantation is conducted.

More specifically, an acceptor-type impurity element such as Mg or C is used where the carriers are electrons, and a donor-type impurity element such as Si is used where the carriers are holes. The impurity element is ion-implanted to be so distributed that the impurity concentration has a peak at a region where carriers are mostly produced, that is, the upper region of the GaN layer. The surface density of the ion-implanted impurity is set to be approximately equal to the surface density of carriers before the ion implantation, taking account of the activation efficiency of the impurity.

The source and drain regions are formed using an impurity which increases the density of carriers induced in regions located on opposite sides of the channel region. Namely, where the carriers are electrons, a donor-type impurity is ion-implanted in these regions, and where the carriers are holes, an acceptor-type impurity is ion-implanted into the regions.

In cases where the activation efficiency of impurity is low, a very large amount of impurity may need to be ion-implanted in order to produce a required quantity of ionized impurity. In such cases, numerous crystal defects may be caused due to ion implantation, possibly deteriorating the characteristics of the resulting device. To avoid the inconvenience, therefore, the ion implantation is preferably conducted with the substrate heated up to a temperature of about 400° C. or higher, thereby increasing the activation efficiency of implanted impurity.

It is to be noted that the present invention can be modified in various ways without departing from the spirit and scope of the invention.

### BRIEF DESCRIPTION OF THE DRAWINGS

FIG. 1 is a diagram showing a state in which a high-resistance GaN crystal layer is formed on a substrate in a production process according to the present invention;

FIG. 2 is a diagram showing a state in which an Si-doped GaN crystal layer is formed on the high-resistance GaN crystal layer in the production process of the present invention;

FIG. 3 is a diagram showing a sectional structure of a GaN FET produced by the production process of the present invention;

FIG. 4 is a diagram showing an exemplary arrangement of an inverter circuit used as a basic logic circuit for digital processing;

FIG. 5 is a diagram illustrating a process of producing an inverter device according to a first embodiment of the present invention, showing a state (semiconductor layer structure) in which a GaN layer and an AlGaN layer constituting a heterojunction are formed on a substrate;

FIG. 6 is a diagram showing a state in which gate electrodes are formed on the AlGaN layer in the inverter device production process according to the first embodiment of the present invention;

FIG. 7 is a diagram showing a state in which a high-concentration donor has been ion-implanted into the AlGaN layer in the inverter device production process according to the first embodiment of the present invention;

FIG. 8 is a diagram showing an inverter device structure in which a first FET of enhancement mode type and a second FET of depletion mode type are formed adjacent to each other by the inverter device production process according to the first embodiment of the present invention;

FIG. 9 is a diagram illustrating a process of producing an inverter device according to a second embodiment of the present invention, showing a state (semiconductor layer structure) in which a GaN layer and an AlGaN layer constituting a heterojunction are formed on a substrate;

FIG. 10 is a diagram showing a state in which gate electrodes are formed on the AlGaN layer in the inverter device production process according to the second embodiment of the present invention;

FIG. 11 is a diagram showing a state in which a high-concentration donor has been ion-implanted into the AlGaN layer in the inverter device production process according to the second embodiment of the present invention; and

FIG. 12 is a diagram showing an inverter device structure in which a first FET of enhancement mode type and a second FET of depletion mode type are formed adjacent to each other by the inverter device production process according to the second embodiment of the present invention.

### DETAILED DESCRIPTION OF THE INVENTION

GaN crystals have a large number of defects therein because of the vacancy of nitrogen etc., and since the vacancy of nitrogen functions in the same way as donor-type impurity, undoped GaN crystals usually show n-type conductivity. This conductivity is canceled out by a process according to the present invention. Specifically, when a GaN crystal layer is formed by epitaxial growth, it is doped in advance with one or more acceptor-type impurities selected from the group consisting of C, Mg and Zn so that the acceptor-type impurity may cancel out the residual carriers that exist due to the aforementioned vacancy, thereby preventing the GaN crystal layer from turning into n-type and increasing the resistance thereof. Namely, the process of the present invention is characterized in that, when a GaN crystal layer, which is to be located under an acceptor-type active layer, is epitaxially grown, it is doped with the above acceptor-type impurity, whereby the resistance of the GaN crystal layer increases.

More specifically, the resistance of the GaN crystal layer is increased in the manner described below.

In a first process according to the present invention, when a GaN crystal layer is epitaxially grown by GS-MBE (gas source molecular beam epitaxy), for example, the epitaxial growth is performed in an atmosphere of H₂ at a high temperature of 600° C. or more, for example, while the layer is doped with Mg or Zn. In this process, Mg or Zn compensates for the residual donor due to its own property as acceptor and also surplus Mg or Zn combines with H, so that the epitaxially grown GaN crystal layer is electrically passivated and is increased in resistance. As a result, when an n-type active layer is formed thereafter on the GaN crystal layer, the GaN crystal layer does not turn into n-type and the resistance thereof does not become low, compared with the active layer. If the epitaxial growth is conducted at a temperature lower than 600° C., the aforementioned combination of elements does not progress satisfactorily.

In a second process according to the present invention, when the GaN crystal layer is epitaxially grown, it is doped by using C as well. In this case, the GaN crystal layer being epitaxially grown is doped with Mg or Zn to reduce the carrier density therein, and is further doped with high-concentration C, whereby the doped C forms a deep level in the GaN crystal layer. As a result, the resistance of the GaN crystal layer can be increased with high stability.

The concentration of Mg or Zn, which is doped to compensate for the carrier density of the GaN crystal layer, is set to 1×10¹⁷ cm⁻³ or less, for example. This is because, if the concentration of Mg or Zn is higher than 1×10¹⁷ cm⁻³, the GaN crystal layer begins to show a p-type property. Also, the doping concentration of C is set to 1×10¹⁸ cm⁻³ or more. If the C concentration is lower than 1×10¹⁸ cm⁻³, the C concentration at a deep level becomes insufficient, making it difficult to increase the resistance with stability.

Embodiments of the present invention will be now described taking the formation of a GaN FET as an example.

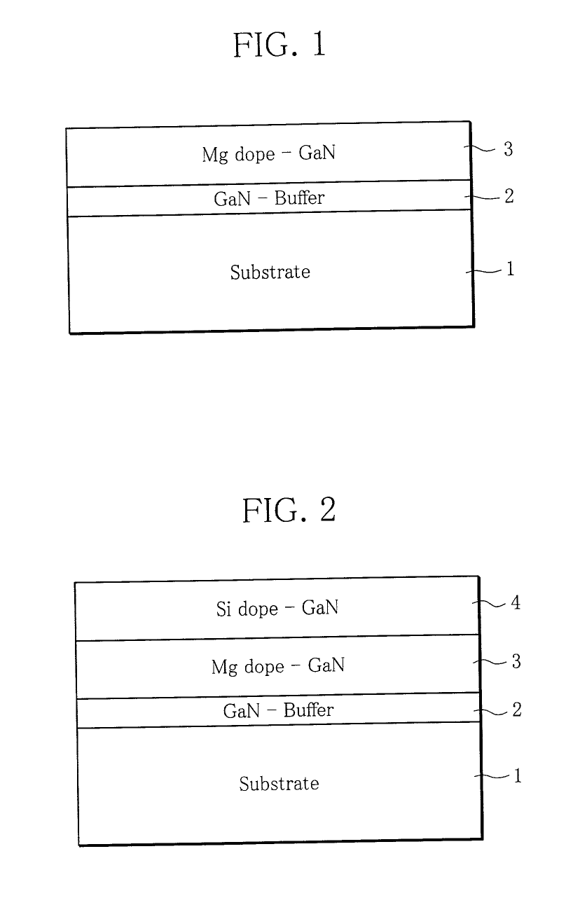

First, using dimethylhydrazine (with flux; 3×10⁻⁶ Torr), metallic Ga (5×10⁻⁷ Torr), metallic Mg (1×10⁻⁸ Torr) and H₂ (5×10⁻⁸ Torr), a GaN crystal layer of 2 nm thick was formed as a buffer layer 2 on a semi-insulating substrate 1 made of sapphire, for example, at a growth temperature of 640° C. by GS-MBE, as shown in FIG. 1. Subsequently, on the buffer layer 2, an Mg-doped GaN crystal layer (Mg doping concentration: 1×10¹⁷ cm⁻³) 3 with a thickness of 1 μm was formed. Then, with the Mg-doped GaN crystal layer 3 exposed to dimethylhydrazine (3×10⁻⁶ Torr), the layer structure was left to stand for 10 minutes at a temperature of 640° C.

Subsequently, using metallic Ga (8×10⁻⁷ Torr) and ammonia (5×10⁻⁵ Torr) and also using Si (1×10⁻⁹ Torr) as an n-type dopant, an n-type Si-doped GaN crystal layer 4 of 30 nm thick was formed on the Mg-doped GaN crystal layer 3 at a growth temperature of 850° C., as shown in FIG. 2. It was ascertained beforehand by Hall measurement that the Si-doped GaN crystal layer 4 formed at this time should have an n-type carrier density of 2×10¹⁷ cm⁻³.

Then, an SiO₂ film was formed over the entire surface of the Si-doped GaN crystal layer 4, and a photoresist was applied to the SiO₂ film, followed by patterning of the photoresist. Using the photoresist as a mask, the SiO₂ film was etched using hydrofluoric acid, thereby forming openings in part of the SiO₂ film.

Subsequently, with the use of an electron cyclotron resonance (ECR) plasma etching system, the openings of the SiO₂ film were exposed to an etching gas which was a plasma gas mixture of methane, argon and hydrogen, and the Si-doped GaN crystal layer 4 was partly etched until the Mg-doped GaN crystal layer 3 was exposed through the openings. The remaining SiO₂ film was then removed in its entirety by etching.

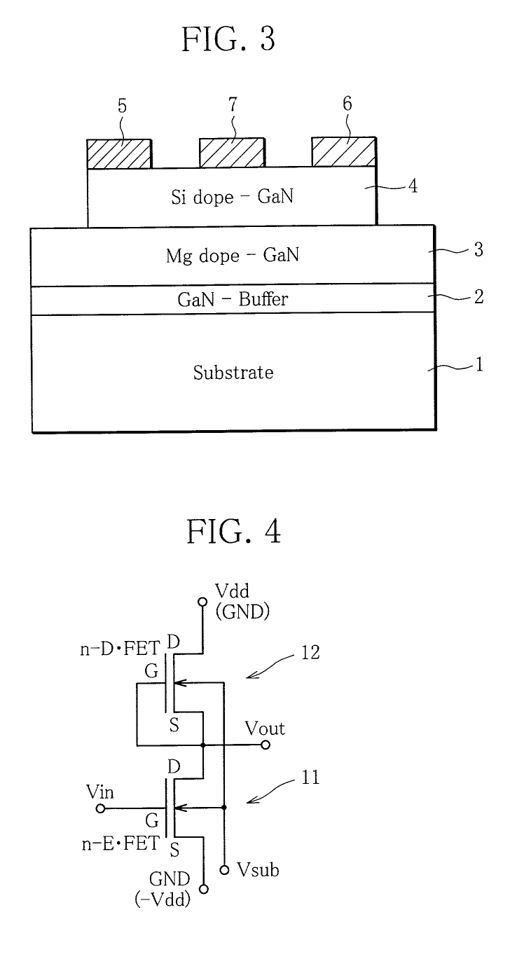

A photoresist was applied to the Si-doped GaN crystal layer 4, and after patterning of the photoresist to make openings where source and drain electrodes were to be formed, Ti/Al was vacuum-deposited on the openings to form source and drain electrodes 5 and 6. The unnecessary Ti/Al was lifted off. Subsequently, a photoresist was again applied to the Si-doped GaN crystal layer 4. After patterning of the photoresist to make an opening where a gate electrode was to be formed, Pt/Au was vacuum-deposited on the opening to form a gate electrode 7, and the unnecessary Pt/Au was lifted off, whereby an FET with a device structure shown in FIG. 3 was obtained.

Electrical characteristics of the FET were evaluated. As a result, the contact resistance between the source and drain electrodes 5 and 6 was 1×10⁻⁶ Ω·cm², and it was also confirmed that each of the electrodes 5 and 6 had an ohmic contact. The gate electrode 7 showed diode characteristics and an operating voltage thereof was 1.1 V. The saturation characteristic of the FET was also satisfactory. From the results of evaluation it was confirmed that the buffer layer 2 and the Mg-doped GaN crystal layer 3 formed by the process according to the present invention both had high resistance.

In the above embodiment, dimethylhydrazine and ammonia were used as the nitrogen source for the epitaxial growth of GaN crystal layers, but plasma nitrogen or radical nitrogen may be used instead. Also, metallic Ga was used as the Ga source, but TEG or TMG may be used instead. Further, although in the foregoing embodiment GS-MBE was employed as an epitaxial growth process, similar results can be obtained with MOCVD.

In the FET produced according to the above embodiment, the Mg-doped GaN crystal layer 3 had a carrier density of 1×10¹⁵ cm⁻³ or less. In this connection, the carrier density of an undoped GaN crystal layer which was not doped with Mg was 1×10¹⁷ cm⁻³. From this it was confirmed that the Mg doping at a concentration of 1×10¹⁷ cm⁻³ served to cancel out the carriers in the undoped GaN crystal layer. An FET was produced in the same manner as in the above embodiment, except that the Mg-doped GaN crystal layer 3 (carrier density: 1×10¹⁵ cm⁻³ or less) was further doped with C at a concentration of 1×10¹⁸ cm⁻³. The FET produced in this manner was evaluated as to electrical characteristics, and as a result it showed characteristics similar to those of the FET produced according to the above embodiment.

As will be seen also from this embodiment, with the process according to the present invention, high-resistance GaN crystal layers can be formed easily. Further, according to the present invention, it is possible to produce GaN FETs capable of operation at high temperatures, proving that the industrial value of the present invention is extremely high.

In the case of producing a GaN FET in the above-described manner, the carrier density should preferably be controlled to optimize the threshold value. Especially, in the case of producing an ED type inverter circuit with a device structure in which an enhancement mode FET (E-FET) and a depletion mode FET (D-FET) are arranged adjacent to each other, it is necessary that the threshold values of these FETs should be optimized.

FIG. 4 shows an example of an inverter circuit comprising an enhancement mode FET (E-FET) 11 as a driver and a depletion mode FET (D-FET) 12 as a load. In the inverter circuit, the E-FET 11 has a source grounded and has a drain connected to the source of the D-FET 12, of which the drain is connected to a power supply voltage Vdd. The gate and source of the D-FET 12 are connected to each other such that an identical potential is applied thereto, whereby the D-FET 12 acts as a load on the E-FET 11, and the E-FET 11 provides, at its drain, an inverted output Vout corresponding to an input voltage Vin applied to the gate thereof.

The threshold value of the E-FET 11, which performs enhancement mode operation, is set to 0.5 V, for example, such that the E-FET is turned on (conductive) when the input voltage Vin is higher than the threshold value and is turned off (cut off) when the input voltage is lower than the threshold value. On the other hand, the threshold value of the D-FET 12, which performs depletion mode operation, is set to −1.0 V, for example, so that the ON (conductive) state thereof is maintained unless a potential lower than the source potential is applied to the gate. Thus, in cases where an inverter circuit is formed such that the E-FET 11 and the D-FET 12 are arranged adjacent to each other on the same substrate, especially where the FETs 11 and 12 are formed using the aforementioned GaN FETs having excellent operation characteristics in high-temperature environments, a problem of how the threshold values of the FETs 11 and 12 should be set (controlled) arises.

According to the present invention, the carrier density of the E-FET 11 and of the D-FET 12 is controlled in the manner describe below, to optimize their respective threshold values, thereby obtaining an inverter circuit having excellent operation characteristics.

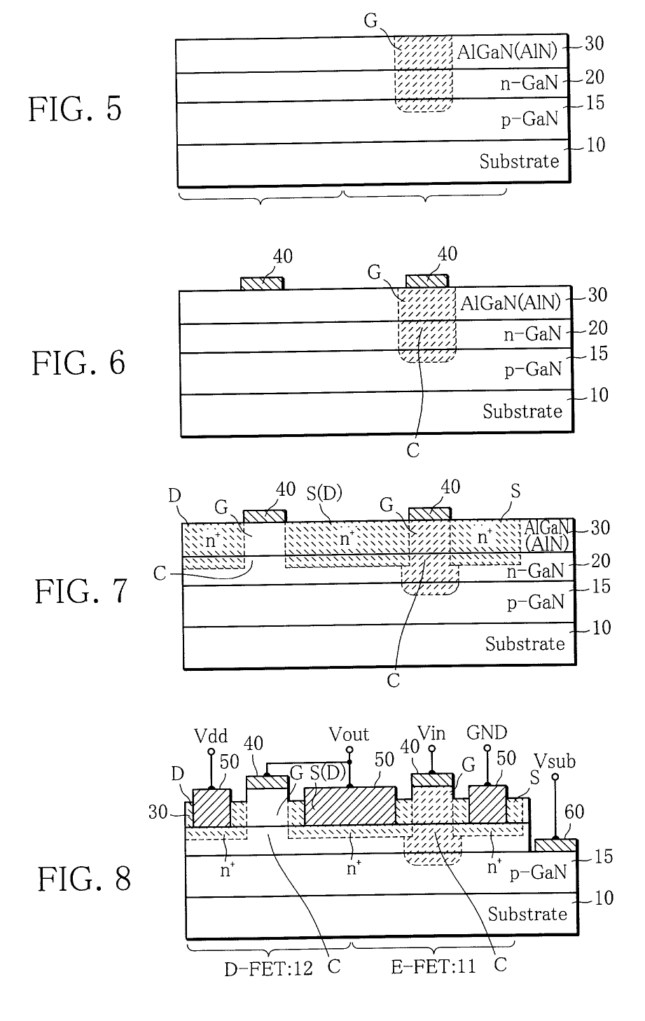

FIGS. 5 through 8 schematically illustrate a process of producing an inverter device according to a first embodiment of the present invention. To produce the inverter device, first, an undoped semi-insulating GaN layer 15 or a high-resistance p-type GaN layer 15 which is doped with an acceptor (Mg, Zn, C, etc.) as stated above is formed on a single-crystal substrate 10 of sapphire, SiC, Si or GaN, for example, as shown in FIG. 5. Then, an n-type GaN layer 20 doped with a donor such as Si is formed on the GaN layer 15, and an AlGaN layer 30 is formed on the GaN layer 20 so as to constitute a heterojunction, thereby forming a multiple epitaxial layer as a device forming material. In place of the AlGaN layer 30, an AlN layer may be formed. The thickness of the AlGaN (AlN) layer 30 is set to about 10 to 30 nm.

Basically, an FET is obtained by forming a gate electrode (metal electrode) 40 on the AlGaN layer 30, wherein the gate has an MIS structure including the AlGaN layer 30 as an intervening layer. Specifically, a gate electrode 40 of metal is formed on a region of the AlGaN layer 30 where the FET is to be formed, as shown in FIG. 6, thereby forming a gate G with MIS structure, and then a high-concentration donor (Si etc.) is ion-implanted into opposite regions of the gate G, as shown in FIG. 7, thus forming n⁺-type source and drain regions S and D. Subsequently, ohmic electrodes 50, 50, which constitute source and drain electrodes, respectively, are formed on the source and drain regions S and D, as shown in FIG. 8, thereby obtaining the FET. The ohmic electrodes 50, 50 constituting the source and drain electrodes are formed after the source and drain regions S and D of the AlGaN layer 30 are removed by alkaline wet etching, dry etching or the like.

In the FET produced in this manner, carriers (electrons) are accumulated at the heterojunction right under the gate electrode 40 even while 0 V (ground potential) is applied the gate electrode 40. Accordingly, the FET constantly remains in an ON state and is turned off only when a potential lower than the source potential is applied to the gate electrode 40. Thus, the D-FET 12 capable of depletion mode operation is obtained.

In this embodiment, prior to the formation of the gate electrode 40, an acceptor (Mg, Zn, C, etc.) is ion-implanted into a region (channel region C) right under a region where the gate G of the E-FET 11 for performing enhancement mode operation is to be formed, as shown in FIG. 5, to cancel out carriers (electrons) inducted at the heterojunction of the channel region. In the ion implantation, the acceptor is implanted in a quantity equivalent to the density of electrons induced at the heterojunction such that the acceptor concentration has a peak at the upper region of the GaN layer 20 close to the AlGaN layer 30. Needless to say, no acceptor is ion-implanted into the region where the D-FET 12 is to be formed.

Thus, the acceptor is ion-implanted in advance into a region right under the gate of the E-FET 11 to control the carrier density of the region; then following the aforementioned procedure shown in FIGS. 6 to 8, the gate electrodes 40, 40 of the E-FET 11 and D-FET 12 are formed, and a high-concentration donor (Si etc.) is implanted into opposite regions of the gate G constituted by each gate electrode 40, to form n⁺-type source and drain regions S and D. Subsequently, the ohmic electrodes 50 are formed on the source and drain regions S and D, whereby the E-FET 11 and the D-FET 12 are formed adjacently to each other.

In the E-FET 11 produced in the above manner in which the acceptor is ion-implanted into the channel region C right under the gate, electrons induced at the heterojunction are canceled out by the ionized acceptor. Accordingly, the E-FET 11 is turned off when 0 V (ground potential) is applied to the gate electrode 40. If a potential higher than the source potential is applied to the gate electrode 40, electrons are induced and thus the E-FET 11 turns on. Consequently, the E-FET 11 performs enhancement mode operation. By following the production procedure described above, moreover, it is possible to form the E-FET 11 and the D-FET 12 adjacently to each other.

Where an inverter circuit as shown in FIG. 4 is to be formed by electrically connecting the E-FET 11 and the D-FET 12, the drain region D of the E-FET 11 and the source region S of the D-FET 12 are formed so as to share a common region, as shown in FIG. 8, and the ohmic electrode 50 formed on the common region is electrically connected to the gate electrode 40 of the D-FET 12.

Also, in practice, a substrate electrode 60 is formed at the GaN layer 20, as shown in FIG. 8, and a substrate potential Vsub is applied to both the E-FET 11 and the D-FET 12. Further, needless to say, the gate lengths of the E-FET 11 and the D-FET 12, the concentration of ions to be implanted, etc. should be appropriately set (designed) to ensure that the resulting inverter circuit has proper operation characteristics.

In the first embodiment described above, the E-FET 11 and the D-FET 12 are formed using the n-type GaN layer 20 as a base, but these FETs 11 and 12 may alternatively be formed using a p-type GaN layer as a base.

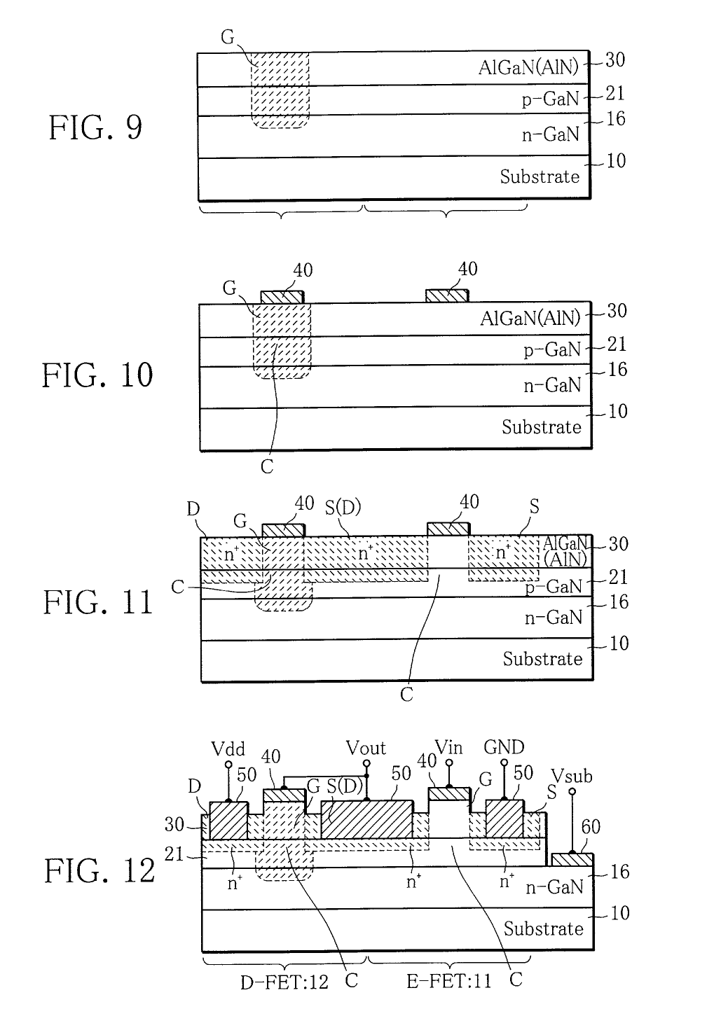

FIGS. 9 through 12 illustrate a second embodiment wherein FETs are formed using a p-type GaN layer 21 as a base. As shown in FIG. 9, first, an undoped semi-insulating GaN layer 16 or an n-type GaN layer 16 which is doped with a donor (Si etc.) is formed on a single-crystal substrate 10 of sapphire, SiC, Si or GaN. Then, a p-type GaN layer 21 doped with Zn or Mg or C as stated above is formed on the GaN layer 16, and an AlGaN layer 30 is formed on the GaN layer 21 so as to constitute a heterojunction, thus preparing a multiple epitaxial layer as a device forming material. Basically, an FET is obtained in a manner similar to the first embodiment, by forming a gate electrode 40 as shown in FIG. 10, to form a gate G with MIS structure, then forming source and drain regions S and D by ion implantation, as shown in FIG. 11, and forming ohmic electrodes 50 on the source and drain regions S and D, as shown in FIG. 12.

In this structure, however, electrons are canceled out by the ionized acceptor contained in advance in the GaN layer 21, and therefore, while no voltage is applied to the gate electrode 40, no electrons are induced at the heterojunction right under the gate. When a positive voltage is applied to the gate electrode 40, electrons are no longer completely canceled out by the ionized acceptor and are induced, so that the FET turns on. Namely, the FET thus constructed performs enhancement mode operation.

In the second embodiment, prior to the formation of the gate electrode 40, a donor is ion-implanted into a region (channel region C) right under a region where the gate G of the D-FET 12 for performing depletion mode operation is to be formed, as shown in FIG. 9, to cancel out the ionized acceptor present at the heterojunction of the channel region. In the ion implantation, the donor is implanted in a quantity equivalent to the density of the ionized acceptor such that the donor concentration has a peak at the upper region of the GaN layer 21 close to the AlGaN layer 30. Also, the donor quantity is set so that while no voltage is applied to the gate G, electrons may be induced at the heterojunction from the outset. Needless to say, no donor is ion-implanted into the region where the E-FET 11 is to be formed.

Thus, the donor is ion-implanted in advance into a region right under the region where the gate G of the D-FET 12 is to be formed, to cancel out the ionized acceptor and allow electrons to be induced in this region, whereby the FET to be formed in the region can be made to function as a depletion mode FET. In addition, the E-FET 11 and the D-FET 12 can be formed adjacently to each other, like the foregoing embodiment.

The ion implantation performed in the above first and second embodiments has good controllability, thus making it possible to control the implantation depth and quantity of implant elements with high accuracy. Consequently, the operating threshold value of the FET can be controlled with high accuracy by controlling the ion implantation. Compared with the case of varying the thickness of the gate G by etching to control the threshold value, therefore, the threshold value can be controlled with much higher accuracy over a wider range.

Also, the ion implantation may be conducted with the substrate heated up to a temperature of about 400° C. or higher, for example, in which case the activation efficiency of ion implantation remarkably increases. However, since the ion implantation is performed with respect to the channel region of the FET, implantation damage or increase in the quantity of ionized impurity in the channel region is unavoidable. Therefore, compared with AlGaAs/GaAs FETs or Si-MOS FETs produced under the same structural (geometric) conditions (e.g., channel length etc.), GaN FETs are poor in operation response (operation speed).

However, GaN FETs, as opposed to AlGaAs/GaAs FETs or Si-MOS FETs, can operate at much higher temperatures and can function as inverter even in an operating environment of, for example, 400° C. Despite poor operation response (operation speed), therefore, GaN FETs are remarkably advantageous in that they can be used in high-temperature environments. Especially, since an inverter circuit, which is a basic logic circuit for digital processing, can be constructed with ease by forming the E-FET 11 and the D-FET 12 adjacently to each other, the GaN FET of the present invention has a wide range of applications.

When forming the source and drain regions S and D, for example, doping of these regions with high-concentration impurity may be performed as needed. Also, donor may be doped to increase the channel electron density, or conversely, acceptor may be doped to lower the channel electron density. Further, by making the doping with the use of the donor or acceptor balanced with the quantity of doping by the aforementioned ion implantation into the channel region C, it is possible to optimize the operation characteristics (inverter characteristics).

In the foregoing description, n-channel type FET is taken as an example, but the technical concepts described above are similarly applicable to the fabrication of p-channel type FET. Further, also in the case of fabricating an EE-type inverter circuit, besides a DE-type inverter circuit, the donor/acceptor implanted into the channel region may be controlled in like manner to optimize the operating threshold value. It should be noted that the present invention can be modified in various ways without departing from the spirit and scope of the invention.

As described above, according to the present invention, a field-effect transistor is produced by forming an AlN or AlGaN layer on a GaN layer to constitute a heterojunction and then forming a gate of MIS structure on the GaN layer with the AlN or AlGaN layer therebetween, and prior to the formation of the gate electrode, ions are implanted into the channel region right under a region where the gate is to be formed, to control the carrier density, whereby the threshold value can be controlled easily with high accuracy. Consequently, it is possible to selectively form with ease a depletion mode field-effect transistor or an enhancement mode field-effect transistor. Further, a depletion mode field-effect transistor and an enhancement mode field-effect transistor, both capable of operation in high-temperature environments, can be formed adjacent to each other, thus providing a remarkable practical advantage.

What is claimed is:

1. A process of forming a high-resistance GaN crystal layer, wherein a GaN crystal is doped with one or more acceptor-type impurities selected from the group consisting of C, Mg and Zn during epitaxial growth thereof.

2. A process of forming a high-resistance GaN crystal layer, wherein a GaN crystal is doped with Mg or Zn in an atmosphere of hydrogen at a temperature of 600° C. or higher during epitaxial growth thereof.

3. A process of forming a high-resistance GaN crystal layer, wherein a GaN crystal is doped with Mg or Zn at a concentration of 1×10¹⁷ cm⁻³ or higher and then doped with C at a concentration of 1×10¹⁸ cm⁻³ or higher during epitaxial growth thereof.

4. A process of forming a high-resistance GaN crystal layer, wherein a GaN crystal is ion-implanted with one or more acceptor-type impurities selected from the group consisting of C, Mg and Zn.

5. A process of forming a high-resistance GaN crystal layer, wherein, with a GaN crystal heated to 400° C. or higher, the GaN crystal is ion-implanted with one or more acceptor-type impurities selected from the group consisting of C, Mg and Zn.

6. A GaN field-effect transistor having a GaN layer, and a gate of MIS structure formed on the GaN layer with an AlN or AlGaN layer therebetween,
wherein said transistor includes a high-resistance GaN crystal layer as a channel region located right under the gate, the high-resistance GaN crystal layer being doped with one or more acceptor-type impurities selected from the group consisting of C, Mg and Zn during epitaxial growth thereof.

7. A GaN field-effect transistor having a GaN layer, and a gate of MIS structure formed on the GaN layer with an AlN or AlGaN layer therebetween,
wherein said transistor includes a high-resistance GaN crystal layer as a channel region located right under the gate, the high-resistance GaN crystal layer being ion-implanted with one or more acceptor-type impurities selected from the group consisting of C, Mg and Zn.

8. An inverter device having a plurality of gates formed adjacent to each other, each of the gates having an MIS structure formed on a GaN layer with an AlN or AlGaN layer therebetween,
wherein one of the adjacent gates includes a high-resistance GaN crystal layer as a channel region located thereunder, the high-resistance GaN crystal layer being doped with one or more acceptor-type impurities selected from the group consisting of C, Mg and Zn during epitaxial growth thereof.

9. An inverter device having a plurality of gates formed adjacent to each other, each of the gates having an MIS structure formed on a GaN layer with an AlN or AlGaN layer therebetween,
wherein one of the adjacent gates includes a high-resistance GaN crystal layer as a channel region located thereunder, the high-resistance GaN crystal layer being ion-implanted with one or more acceptor-type impurities selected from the group consisting of C, Mg and Zn.

10. The inverter device according to claim 8 or 9, wherein the adjacent gates comprise a gate of a first field-effect transistor for performing enhancement mode operation and a gate of a second field-effect transistor for performing depletion mode operation.

11. A process of producing a GaN field-effect transistor, comprising:
forming an AlN or AlGaN layer on a GaN layer to constitute a heterojunction;
ion-implanting a predetermined quantity of one or more acceptor-type impurities selected from the group consisting of C, Mg and Zn, into a predetermined region of the GaN layer to form a channel region;
forming a gate electrode on a region of the AlN or AlGaN layer located over the ion-implanted channel region; and
forming source and drain regions in regions of the AlN or AlGaN layer located on opposite sides of the channel region.

12. A process of producing an inverter device, comprising:
forming an AlN or AlGaN layer on a GaN layer to constitute a heterojunction;
ion-implanting a predetermined quantity of one or more acceptor-type impurities selected from the group consisting of C, Mg and Zn, into one of a plurality of channel regions in the GaN layer situated adjacent to each other;
forming a gate electrode on a region of the AlN or AlGaN layer located over each of the channel regions; and
forming source and drain regions in regions of the AlN or AlGaN layer located on opposite sides of each of the channel regions.

13. A process of producing an inverter device, comprising:
forming an AlN or AlGaN layer on a GaN layer to constitute a heterojunction;
ion-implanting a predetermined quantity of one or more acceptor-type impurities selected from the group consisting of C, Mg and Zn, into each of a plurality of regions in the GaN layer situated adjacent to each other, to form a plurality of channel regions;
ion-implanting a donor-type impurity into one of the adjacent channel regions to control carrier density thereof;
forming a gate electrode on a region of the AlN or AlGaN layer located over each of the channel regions; and
forming source and drain regions in regions of the AlN or AlGaN layer located on opposite sides of each of the channel regions.
